(19) United States
(12) Patent Application Publication
(10) Pub. No.: US 2008/0239942 A1
(43) Pub. Date: Oct. 2, 2008

(54) SYSTEMS AND METHODS FOR VERIFYING RECOVERY FROM AN INTERMITTENT HARDWARE FAULT

(75) Inventors: Joe S. Hsu, San Jose, CA (US); Mark C. Johnson, San Jose, CA (US); Hugh W. McDevitt, San Jose, CA (US)

Correspondence Address: CANTOR COLBURN LLP - IBM TUSCON DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/693,206

(22) Filed: Mar. 29, 2007

(51) Int. Cl. G01R 31/08

(52) U.S. Cl. 370/216

(57) ABSTRACT

Systems and methods for verifying recovery from intermittent hardware faults. Exemplary embodiments include a method for verifying recovery from intermittent hardware faults, the method including generating an error in a computer interface by forcing a hardware fault after setting an error injection enable control bit in a register coupled to the computer interface, detecting an error in a hardware checker coupled to the computer interface which asserts an error interrupt signal resetting the error injection enable control bit when the error interrupt signal and a hardware reset control bit coupled to the computer interface are both active, disabling error forcing when the error injection enable control bit is reset, and executing an error recovery and logging procedure in the computer interface.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

The invention relates to intermittent hardware fault recovery, and particularly to systems and methods for verifying recovery from intermittent hardware faults.

2. Description of Background

Computing systems often have the ability to inject errors into the system to facilitate testing of error detection and recovery procedures. In many systems, software is required to control the duration of the error by writing to a control bit to start and stop the error injection. However, a drawback to this current solution is that the error forcing may not be maintained long enough so that the hardware checker can detect the error being forced. In addition, if error forcing is maintained too long the system may not recover completely from the error injection. Additional solutions are needed to ensure that error recovery is successful.

### SUMMARY OF THE INVENTION

Exemplary embodiments include a method for verifying recovery from intermittent hardware faults. The method generally includes setting an error injection enable control bit in a register coupled to the computer interface forcing a hardware fault to be generated in the computer interface, detecting an error in a hardware checker coupled to the computer interface as a consequence of this hardware fault, resetting the error injection enable control bit and thus disabling error forcing as well as executing error recovery and logging in the computer interface as a consequence of this error.

Additional exemplary embodiments include a system for verifying recovery from intermittent hardware faults. The system generally includes a computer interface, a hardware checker operatively coupled to the computer interface, an error injector operatively coupled to the computer interface and to the hardware checker, the error injector generating error injection on hardware (e.g., external bus, normal logic, etc.,) and a process for monitoring, managing and verifying recovery from the intermittent hardware faults. The process generally includes instructions to force a hardware fault via the interface, the hardware fault being detectable by the hardware checker, detecting an unmasked error within the hardware checker, ceasing error forcing and executing error recovery and logging procedures within the computer interface. Wherein registers that are coupled to the computer interface, hardware checker and error injector consist of an error injection enable control bit that can be et to enable an error injection code to start error forcing and a hardware reset control bit, wherein detecting an error interrupt signal results the error injection enable control bit which subsequently disables error forcing, the error interrupt signal being active while there exists unmasked error interrupts in the computer interface.

System and computer program products corresponding to the above-summarized methods are also described and claimed herein.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

As a result of the summarized invention, systems and methods have been achieved that ensure error forcing is maintained long enough that an error can be detected in a hardware error detector, and further ensure that error forcing is ceased prior to executing hardware error recovery so that a system can recover from this error injection.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates an exemplary system diagram for an error injection, hardware fault detector and recovery system; and

FIG. 2 illustrates an exemplary method for verifying recovery from intermittent hardware faults.

The detailed description explains the preferred embodiments of the invention, together with advantages and features, by way of example with reference to the drawings.

### DETAILED DESCRIPTION OF THE INVENTION

Exemplary embodiments include systems and methods to verify successful recovery from an intermittent hardware fault. In general, the systems and methods sustain error forcing for a time period adequate for a hardware checker to be set. Furthermore, in exemplary implementations, the system can recover completely from the error injection. In further exemplary implementations, the hardware error forcing is terminated before the firmware error recovery is invoked. In general, prescribed error recovery procedures can vary dependent on the particular hardware fault injected. These procedures can be defined on the particular the system hardware/microcode integration.

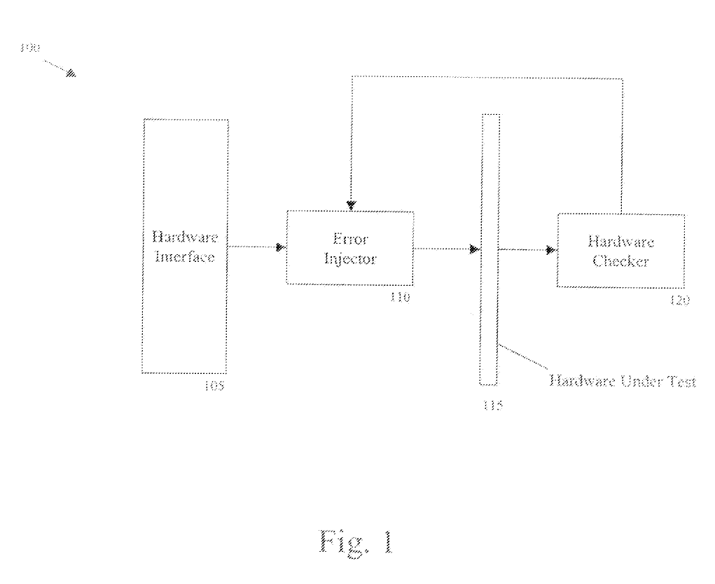

FIG. 1 illustrates an exemplary system diagram for an error injector, hardware fault detector and recovery system 100. In general, system 100 can include any suitable hardware or firmware interface 105, such as but not limited to an IEEE Joint Test Action Group (JTAG) interface. System 100 further includes an error injector 110 coupled to the hardware interface 105 and to hardware under test 115, which is coupled to a hardware checker 120. Furthermore, the hardware checker is further coupled to the error injector 110. In general, the interface 105 can be the source or can receive and process various signals such as bus CLK signals, various bus cycle and transaction signals, bus error signals, etc. In an exemplary implementation, as discussed further below, the interface 105 can be actuated so as to generate an appropriate bus cycle that enables error injection. As mentioned above, system 100 further includes the hardware under test 115 that is coupled to both the error injector 110 and to the hardware checker 120. In general, error injector 110, upon being enabled, injects an error onto the hardware under test 115, which can be done, for example, by overdriving the selected hardware to a logical state opposite the correct state for a given bus cycle or transaction. In an exemplary implementation, system 100 can include software indicators for indicating readiness of system 100 to inject an error, current injection of an error, successful injection of an error, or any other useful information regarding operation of system 100. In general, a user can enable the system for various error injection protocols. For example, a user can selectively control whether system 100 attempts a single error injection onto the hardware under test 115 or continues error injection attempts on successive bus cycles or transactions until an error is successfully injected. In general, feedback from the hardware checker is input into the error injector 110. The initial input from the hardware interface 105 indicates the capability of that hardware interface 105 to instruct the error injector 110 to start and stop error injection. The input from the hardware checker 120 into the error injector 110 indicates the capability of the hardware checker 120 to instruct the error injector 110 to stop error injection. It is appreciated that the hardware under test 115 can be either an external or internal bus. In an exemplary embodiment, the hardware interface 105, the error injector 110, the hardware under test 115, and the hardware checker 120 are implemented within a single ASIC (application specific integrated circuit).

In an exemplary embodiment, interface 105 can identify a fault signal and monitor the system 100 for the appropriate transaction in which to inject the desired fault. The interface 105 further provides the stimulus for setting the enable signal which controls error injector 110 which ultimately injects the fault on the hardware under test 115 and also monitors the error-reporting signals. When an assertion of an activation signal is detected (and latched), the hardware interface 105 waits until a system transaction corresponding to the transaction into which the desired fault to be injected is recognized. Hardware interface 105 then asserts an error enable signal to error injector 110.

As such, system 100 can be implemented to force a particular hardware fault via hardware interface 105, which is detectable by a specific hardware checker such as hardware checker 120. Once hardware detects any unmasked error, for example, the error forcing ceases. The system 100 can then execute its error recovery and logging procedure as indicated by the particular error indicator that was set as a result of the error that was forced. Subsequently system 100 activity can then resume as if the error had never occurred.

The following description is an example embodiment of the above-described system 100. It is appreciated that in an exemplary embodiment, the hardware checker 120 can monitor and control error injection from the hardware interface 105 to the error injector 110. As such, hardware checker 120 can include one or more registers that allow both error injection as well as the ability to detect the error injection from the interface while the specific error or transaction from the hardware interface 105 can be detected. As such, error forcing from the hardware interface 105 is maintained long enough for hardware checker 120 to be set, thereby detecting the error. In an exemplary implementation an Error Injection Enable Control (err_inj_en) bit can be set in the registers to enable the error injection code. Setting this bit active enables the error injection code to start error forcing and resetting this bit disables the error injection code to stop error forcing. This bit can be written by either hardware or firmware (e.g. software, microcode, etc.). In addition, a Hardware Reset Control bit can also be controlled by firmware. If firmware turns this control bit on, then hardware resets err_inj_en to zero whenever the signal any_int is asserted. Hardware sets any_int active whenever any unmasked error interrupt is reported, indicating that the injected error has been detected. This signal remains active until all unmasked error interrupts are cleared by firmware.

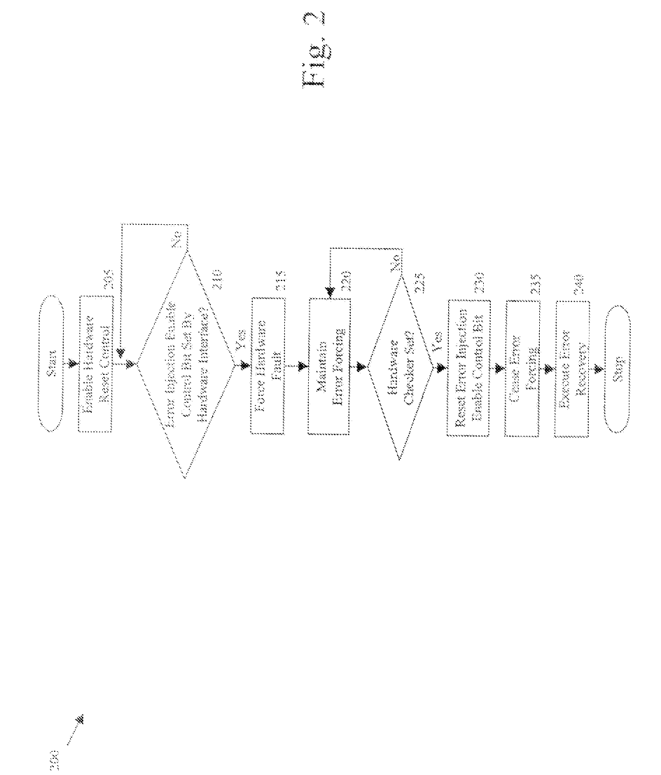

FIG. 2 illustrates an exemplary method 200 for verifying recovery from intermittent hardware faults. As discussed above, firmware can first enable the hardware-reset control at step 205 to allow hardware rather than firmware to cease error forcing. The hardware interface 105 under the control of firmware sets the error injection enable control bit. At step 210, the method 200 checks to ascertain whether or not the error injection enable control bit has been set by the hardware interface. If not, then the loop repeats. If at step 210, the error injection enable control bit has been set, then a hardware fault is forced at step 215. Error forcing is maintained at step 220. At step 225, a determination is made whether or not the hardware checker 120 is set, that is, whether an error has been detected. If at step 225, the hardware checker has been set, then at step 230, the error injection enable control bit is reset. Then at step 235, error forcing is disabled. At step 240, the system 100 can then initiate its error recovery. As discussed above, the system 100 executes the error recovery and logging procedure as indicated by the particular error indicator that was set as a result of the error that was forced. System 100 activity can then resume as if this error had never occurred.

It is appreciated that the method 200 is re-executed whenever the Hardware Interface 105 sets the Error Injection Enable Control Bit. In an exemplary implementation, the Error Injection Enable Control bit can be set either by the JTAG interface or by system firmware.

Therefore, as discussed above, system 100 can be implemented to force a particular hardware fault via interface 105, which is detectable by a specific hardware checker such as hardware checker 120. Once hardware detects any unmasked error, for example, the error forcing ceases.

This method 200 helps ensure that the error forcing be sustained long enough for the hardware checker 120 to be set. The method 200 also helps ensure that the system 100 should be able to recover completely from the error inject since the hardware error forcing is stopped before the system 100 error recovery is invoked.

The capabilities of the present invention can be implemented in software, firmware, hardware or some combination thereof.

As one example, one or more aspects of the present invention can be included in an article of manufacture (e.g., one or more computer program products) having, for instance, computer usable media. The media has embodied therein, for instance, computer readable program code means for providing and facilitating the capabilities of the present invention. The article of manufacture can be included as a part of a computer system or sold separately.

Additionally, at least one program storage device readable by a machine, tangibly embodying at least one program of instructions executable by the machine to perform the capabilities of the present invention can be provided.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method for verifying recovery from intermittent hardware faults, the method consisting of:
setting a hardware reset control bit in a register coupled to a computer interface;
forcing a hardware fault by setting an error injection enable control bit in a register coupled to the computer interface;
maintaining the hardware fault as long as the error injection enable control bit remains active;
detecting an unmasked error in a hardware checker coupled to the computer interface;
resetting the error injection enable control bit when an unmasked error is detected;
disabling error forcing when the error injection enable control bit is reset; and
executing an error recovery and logging procedure in the computer interface.

2. The method as claimed in claim 1 further consisting of determining the existence of any additional errors and interrupts on the computer interface.

3. A system for verifying recovery from intermittent hardware faults, the system consisting of:
a computer interface;
a hardware checker operatively coupled to the computer interface;
an error injector operatively coupled to the computer interface and to the hardware checker, the error injector generating error injection on the hardware; and
a process for monitoring, managing and verifying recovery from the intermittent hardware faults, the process including instructions to:
force the hardware fault via the interface, the hardware fault being detectable by the hardware checker;
detect an unmasked error within the hardware checker;
cease error forcing; and
execute error recovery and logging procedures within the computer interface,
wherein registers that are coupled to the computer interface, hardware checker and error injector, consist of:
an error injection enable control bit that can be set to enable an error injection code to start error forcing, wherein resetting the error injection enable control bit disables error forcing; and
a hardware reset control bit that resets the error injection enable control bit when the hardware reset control bit is enabled and an error interrupt signal is active, the interrupt signal being active while there exist unmasked error interrupts in the computer interface.

4. The system as claimed in claim 3 wherein the hardware checker monitors and controls error injection from the computer interface.

5. The system as claimed in claim 4 wherein error forcing is maintained on the hardware until the hardware checker detects the error.
